(19) United States
(12) Patent Application Publication
(10) Pub. No.: US 2008/0128783 A1
(43) Pub. Date: Jun. 5, 2008

(54) SPLIT-GATE NON-VOLATILE MEMORY CELLS INCLUDING RAISED OXIDE LAYERS ON FIELD OXIDE REGIONS

(76) Inventors: Hee-Seog Jeon, Gyeonggi-do (KR); Seung-Beom Yoon, Gyeonggi-do (KR); Jeong-Uk Han, Gyeonggi-do (KR); Yong-Tae Kim, Gyeonggi-do (KR)

Correspondence Address: MYERS BIGEL SIBLEY & SAJOVEC, PO BOX 37428, RALEIGH, NC, 27627, US

(21) Appl. No.: 12/027,771

(22) Filed: Feb. 7, 2008

Related U.S. Application Data
(62) Division of application No. 11/138,702, filed on May 26, 2005, now Pat. No. 7,351,636.

(30) Foreign Application Priority Data
Jul. 12, 2004 (KR) 2004-0054050

(51) Int. Cl. H01L 29/788

(52) U.S. Cl. 257/316; 257/E29.3

(57) ABSTRACT

A split-gate non-volatile memory device includes a raised oxide layer on a field oxide region between adjacent split-gate memory cells, the raised oxide layer extending onto first and second floating gates included in the adjacent split-gate memory cells covered by a wordline electrically coupled to respective control gates included in the adjacent split-gate memory cells.

### CROSS-REFERENCE TO RELATED APPLICATION

This application claims priority to and is a divisional of parent application Ser. No. 11/138,702, filed May 26, 2005, the disclosure of which is hereby incorporated herein by reference, which claims the benefit of Korean Application No.: 10-2004-0054050, filed in the Korean Intellectual Property Office on Jul. 12, 2004, which is incorporated herein by reference.

### FIELD OF THE INVENTION

The invention relates generally to the field of semiconductors and more particularly to non-volatile semiconductor memory cells.

### BACKGROUND

Non-volatile memory devices are used in a wide range of applications where a power supply may not always be available. For example, non-volatile memory devices are sometimes used to store data in cellular telephones, smart cards, and personal computers. One type of non-volatile memory device is referred to as a split-gate non-volatile memory an example of which is illustrated in FIG. 1. In operation, the split-gate memory cell can be programmed with data by transferring charge to a floating gate 6 using hot carrier injection as indicated by arrow 1 in FIG. 1. The split-gate memory cell can be erased by discharging the stored charge from the floating gate 6 via a control gate 5 as indicated by arrow 2. Once the split-gate memory cell is programmed or erased as desired, the data stored in the split-gate memory cell can be accessed by reading the split-gate memory cell.

As shown in FIG. 1, a conventional split-gate memory cell can be formed in conjunction with an opposing split-gate memory cell where both opposing split-gate memory cells are arranged in a common source configuration. In particular, a common source region 4 can be electrically coupled to separate opposing drain regions 3 via each of the opposing split-gate memory cells. In operation, the common source 4 can be electrically coupled to either of the drain regions 3 by applying the appropriate voltages to the respective floating gate 6 and control gate 5 included in each of the opposing split-gate memory cells.

It is known that split-gate memory cells provide several advantages over other types of non-volatile memories, such as low programming current, low interference, as well as high speed. Split-gate memory cells can also carry several disadvantages such as relatively large size compared to other types of non-volatile memory cells.

It is also known that if the distance (D1 and D2) that the control gate overlaps the active area excessively varies from cell-to-cell, the amount of current generated in the different memory cells may vary enough that memory cells may not operate predictably. The following references discuss several types of split-gate memory cells as well as different approaches to the formation thereof: U.S. Pat. No. 4,328,565, U.S. Pat. No. 4,616,340, U.S. Pat. No. 4,783,766, U.S. Pat. No. 5,291,439, U.S. Pat. No. 5,317,179, U.S. Pat. No. 5,341,342, U.S. Pat. No. 5,373,465, 2000-75049 (Korea File: December 2000: SEC B), and U.S. Pat. No. 6,727,545.

Notwithstanding the various approaches discussed above and in the listed references, there remains a need for improvement in the formation of split-gate memory cells and related devices.

### SUMMARY

In some embodiments according to the invention, a split-gate non-volatile memory device includes a raised oxide layer on a field oxide region between adjacent split-gate memory cells, the raised oxide layer extending onto first and second floating gates included in the adjacent split-gate memory cells covered by a wordline electrically coupled to respective control gates included in the adjacent split-gate memory cells.

In some embodiments according to the invention, central upper portions of the first and second floating gates are lower than a surface of the field oxide region. In some embodiments according to the invention, the raised oxide layer is a thermally oxidized polysilicon layer. In some embodiments according to the invention, the floating gates are self aligned to the field oxide regions. In some embodiments according to the invention, the raised oxide layer extends onto the active region to cover the floating gates.

In some embodiments according to the invention, the raised oxide layer on the field oxide region is thinner than a portion of the raised oxide layer that extends onto the active region to cover the first and second floating gates. In some embodiments according to the invention, the device further includes a first spacer on a side wall of the control gates above the floating gates and a second spacer on side walls of the raised oxide layer and the floating gates.

In some embodiments according to the invention, a split-gate non-volatile memory device includes first and second adjacent floating gates self-aligned to a field oxide region therebetween. An oxide layer covers the first and second adjacent floating gates and the field oxide region, and the oxide layer electrically isolates the first and second adjacent floating gates from one another. A control gate is on the oxide layer on the first and second adjacent floating gates.

In some embodiments according to the invention, central upper portions of the first and second floating gates are lower than a surface of the field oxide region. In some embodiments according to the invention, the oxide layer is a thermally oxidized polysilicon layer. In some embodiments according to the invention, the oxide layer extends onto the active region to cover the floating gates. In some embodiments according to the invention, the oxide layer on the field oxide region is thinner than a portion of the oxide layer that extends onto the active region to cover the first and second floating gates. In some embodiments according to the invention, the device further includes a first spacer on a side wall of the control gates above the floating gates and a second spacer on side walls of the oxide layer and the floating gates.

### BRIEF DESCRIPTION OF THE DRAWINGS

FIG. 1 is a cross-sectional view that illustrates a conventional split-gate memory cell in a common source configuration.

FIG. 2 is a top view of a substrate including pairs of opposing split-gate memory cells arranged between adjacent field oxide regions according to some embodiments of the invention.

FIG. 3 is a top view of a substrate including split-gate memory cells according to some embodiments of the invention.

FIGS. 4A-C are cross-sectional view of split-gate memory cells according to some embodiments of the invention.

FIG. 5 is a cross-sectional view of split-gate memory cells according to some embodiments of the invention.

FIGS. 6A-C through FIGS. 20A-C are cross-sectional views illustrating the formation of split-gate memory cells according to some embodiments of the invention.

FIGS. 20A-C through FIGS. 21A-C are cross-sectional views illustrating the formation of split-gate memory cells according to further embodiments of the invention.

FIGS. 22A-C through FIGS. 27A-C are cross-sectional views illustrating the formation of split-gate memory cells according to further embodiments of the invention.

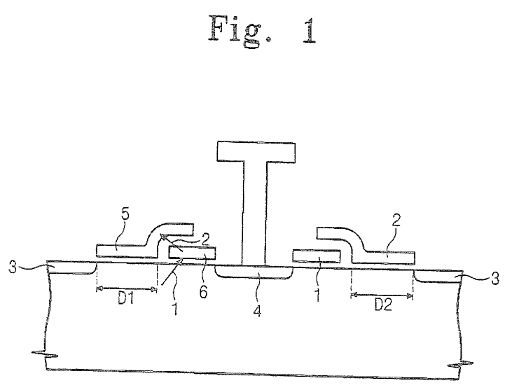

### DESCRIPTION OF EMBODIMENTS ACCORDING TO THE INVENTION

The invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. As used herein the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Furthermore, relative terms, such as “lower”, “bottom”, “upper”, “top”, “beneath”, “above”, and the like are used herein to describe one element's relationship to another elements as illustrated in the Figures. It will be understood that relative terms are intended to encompass different orientations of the subject in the figures in addition to the orientation depicted in the Figures. For example, if the subject in the Figures is turned over, elements described as being on the “lower” side of or “below” other elements would then be oriented on “upper” sides of (or “above”) the other elements. The exemplary term “lower”, can therefore, encompasses both an orientation of “lower” and “upper,” depending of the particular orientation of the figure. Similarly, if the subject in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross-section (and/or plan view) illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated or described as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will also be appreciated by those of skill in the art that references to a structure or feature that is disposed “adjacent” another feature may have portions that overlap or underlie the adjacent feature.

As described herein below in greater detail, in some embodiments according to the invention, an oxide layer can be formed to cover first and second adjacent floating gates and a field oxide region, wherein the oxide layer electrically isolates the first and second adjacent floating gates from one another. For example, the oxide layer can extend from on the active region above the floating gate onto the adjacent field oxide region. Furthermore, the portion of the oxide layer that extends onto the field oxide region can be raised relative to the oxide layer that is above the floating gate.

Accordingly, a surface of the raised oxide layer is at a higher level than a surface of the oxide layer located above the floating gate. Extending the oxide layer from on the floating gate to on the field oxide region (and further onto the floating gate in the adjacent memory cell) can electrically isolate the floating gates in the adjacent memory cells from one another. Furthermore, the floating gates can be formed self-aligned to the field oxide regions (and isolated from one another via the oxide layer including the raised oxide layer on the field oxide between adjacent split-gate memory cells). The oxide layer including the raised oxide layer on the field oxide region may improve the self-alignment of the floating gates in forming the split-gate memory cells according to some embodiments of the invention.

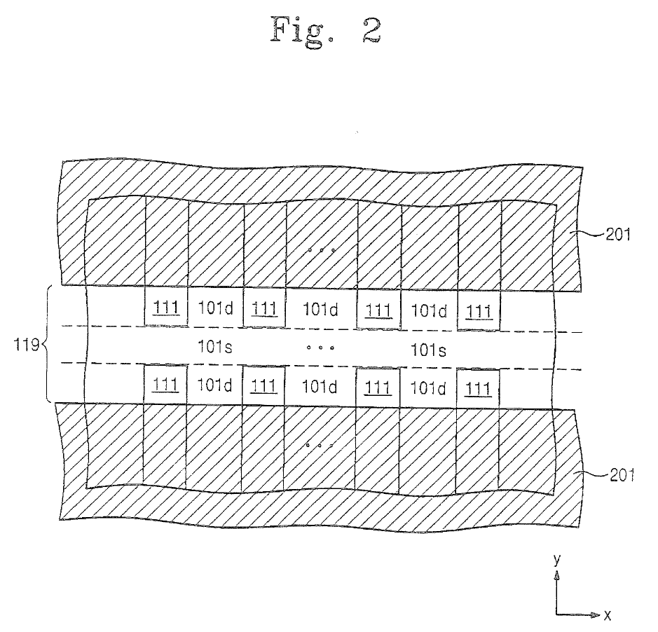

FIG. 2 is a top view of a substrate including active regions 101d and 101s. The active regions 101d and 101s correspond to regions where drains and sources are to be formed for split-gate memory cells according to some embodiments of the invention using a mask 102 including an opening 119. Opposing active regions 101d correspond to respective drain regions associated with opposing split-gate memory cells to be formed thereon in the “y” direction are shown in FIG. 2. Furthermore, active region 101s refers to a source region that provides a common source configuration for the opposing split-gate memory cells. The opposing split-gate memory cells are separated from adjacent opposing split-gate memory cells by field oxide regions 111 in the “x” direction are shown in FIG. 2.

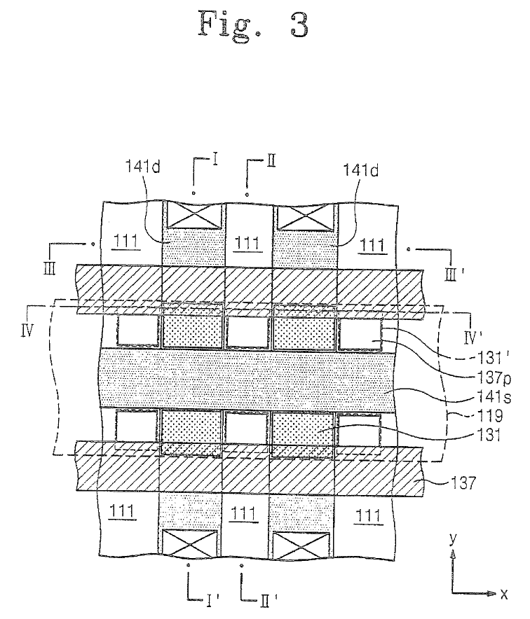

FIG. 3 is a top view of a substrate including a number of opposing split-gate memory cells that are separated from adjacent ones of the split-gate memory cells in the x direction by field oxide regions 111. Referring to FIG. 3, a source region 141s extends in the x direction and is located between opposing split-gate memory cells arranged in the y direction to provide the common source configuration for the opposing split-gate memory cells when formed.

Each of the opposing split-gate memory cells includes a respective floating gate located between the field oxide regions 111 and partially over the common source region 141s. A remaining portion of the floating gate is formed over the portion of the active region that separates the respective drain region from the common source region 141s. An oxide layer 131 is on the floating gate between the field oxide regions 111. The oxide layer 131 extends from on the floating gate therebeneath onto the field oxide regions 111 in the x direction.

It will be understood that the portion of the oxide layer 131 that extends onto the field oxide region 111 is raised relative to the oxide layer 131 to a level above the floating gate. Moreover, the oxide layer extending onto the field oxide region 111 can continuously extend onto floating gates included in adjacent ones of the split-gate memory cells, and further, can extend onto the field oxide region 111 that separates that split-gate memory cell from its next adjacent neighbor in the x direction. Accordingly, the portion of the oxide layer that extends from on the floating gate onto the field oxide region 111 is referred to as a raised oxide layer 131′ as shown in FIG. 3.

A control gate (or word line) 137 is on a portion of the active region that separates the common source region 141s from the respective drain region 141d and extends vertically adjacent to and above the oxide layer 131 and covers a portion of the oxide layer 131 over the floating gate. Furthermore, a portion of the control gate 137p extends above the raised oxide layer 131′ on the field oxide regions 111.

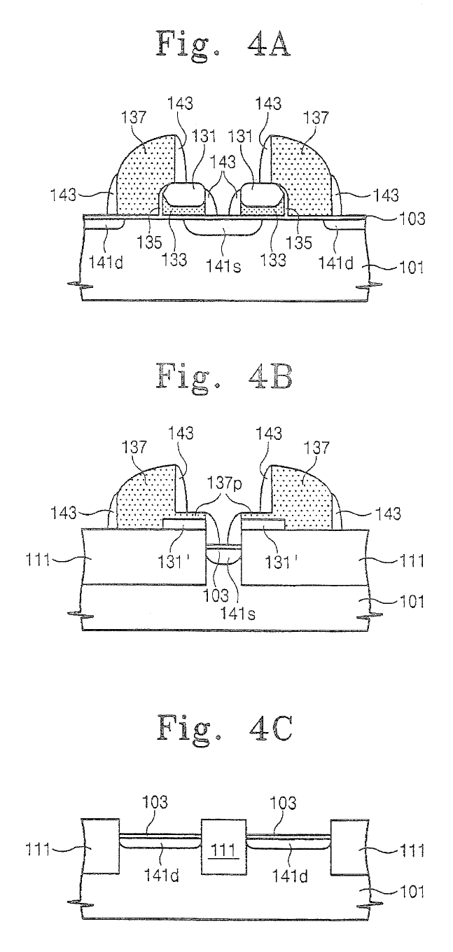

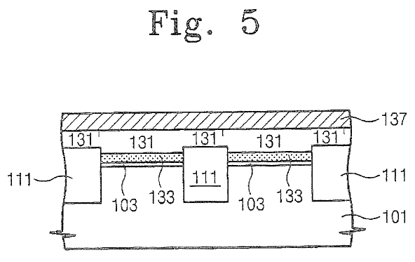

FIGS. 4A-C and FIG. 5 are cross-sectional views, taken along lines I-I′, II-II′, III-III′, and IV-IV′ respectively in FIG. 3, that illustrate split-gate memory cells according to some embodiments of the invention. Referring to FIGS. 4A-C and FIG. 5, respective drain regions 141d in the substrate 101 are separated from a common source region 141s. An oxide layer 103 is on the substrate 101 and can electrically isolate the floating gate 131 and control gate 137 from the active regions of the substrate 101. The floating gate 133 partially covers a portion of the common source region 141 and portions of the substrate 101 separating the respective drain regions 141d from the common source region 141s. The remaining portion of the substrate 101 that separates the respective drain regions 141d from the common source region 141s is covered by the control gate 137 thereon.

The control gate 137 extends vertically adjacent to a sidewall of the floating gate 131 and the oxide layer 131 located above the floating gate 133. Furthermore, the control gate 137 extends to cover a portion of the oxide layer 131. Spacer 135 electrically isolates the floating gate 133 from the adjacent portion of the control gate 137 that extends vertically along the sidewall thereof. Furthermore, spacer 143 can promote the formation of the respective drain regions 141d and the common source region 141s as well as provide electrical isolation of the floating gate 133 and control gate 137 from adjacent conductive structures such as plugs, etc. that can provide access to the respective drain regions 141d and the common source region 141s.

Referring specifically to FIG. 4B, the raised oxide layer 131′ is provided by the extension of the oxide layer 131 located on the floating gate 133 onto the field oxide layer 111. Therefore, the raised oxide layer 131′ is at a higher level than the oxide layer 131. A central upper portion of the floating gate 133 is lower than the adjacent upper surface of the field oxide region 111. Furthermore, an extension portion 137p of the control gate 137 covers the raised oxide layer 131′ that is above the field oxide region 111.

Referring specifically to FIG. 5, the floating gates 133 are formed between the field oxide regions 111 and are self-aligned thereto. Furthermore, the oxide layer 131 and the raised oxide layer 131′ are formed on the floating gate 133 and on field oxide regions 111 and extend continuously in the x direction. The oxide layer 131 and the raised oxide layer 131′ can electrically isolate the floating gates 133 from one another and from the control gate 137 thereon. As shown in FIG. 5, the portion of the oxide layer 131 referred to as the raised oxide layer 131′ is thinner than the oxide layer that covers the floating gate 133 (i.e., the oxide layer 131). In some embodiments according to the invention, the oxide layer 131 can be a thermally oxidized polysilicon layer.

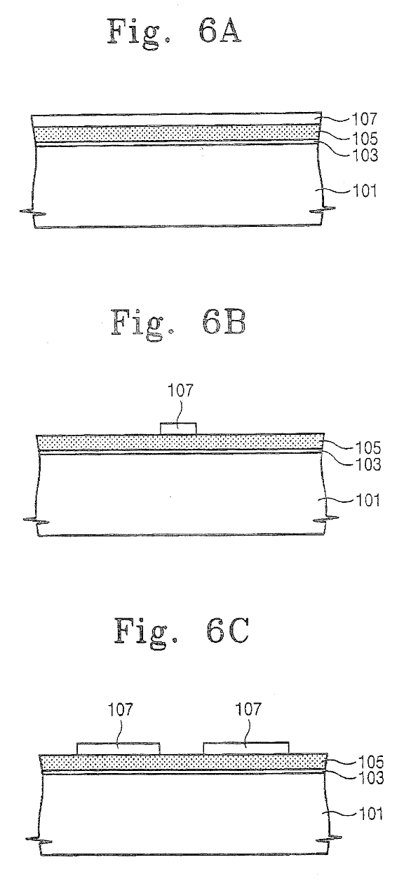

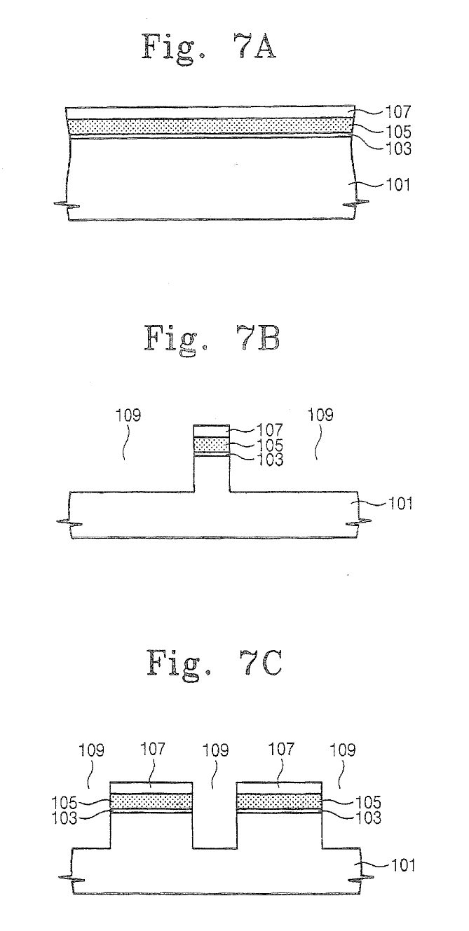

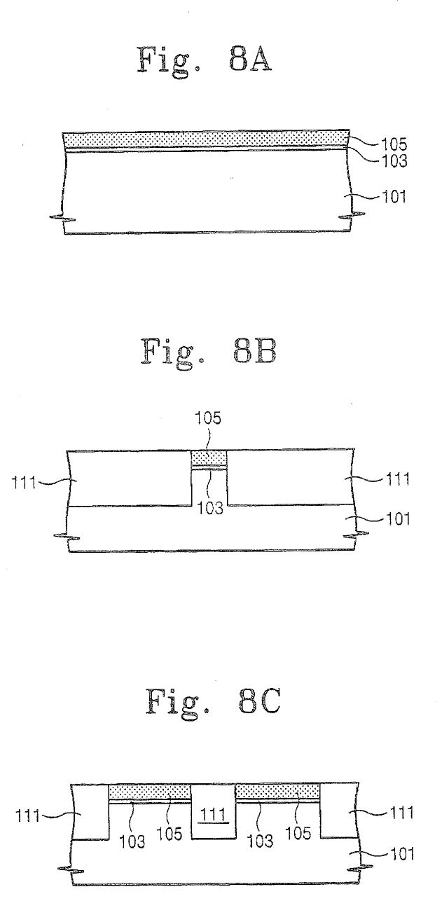

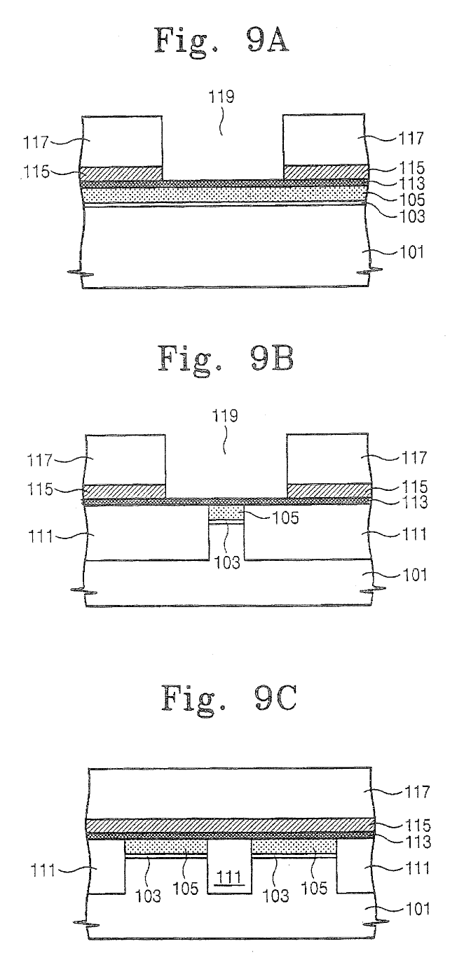

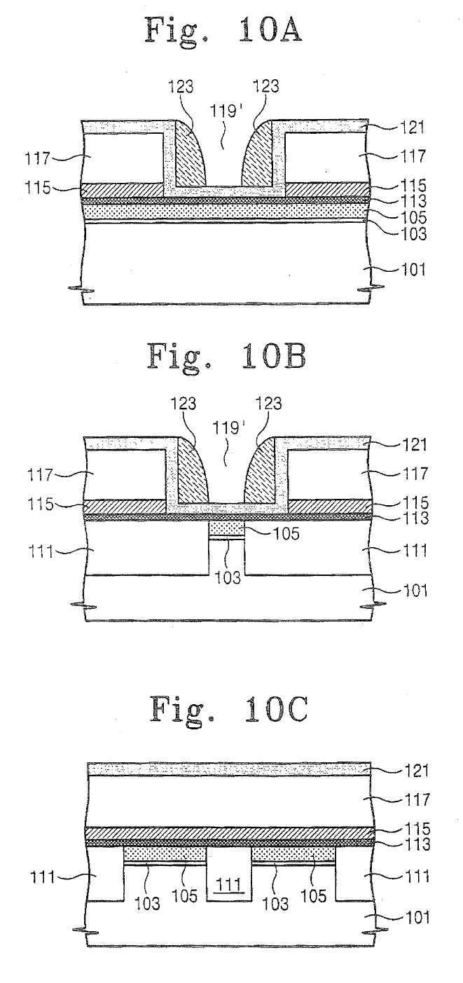

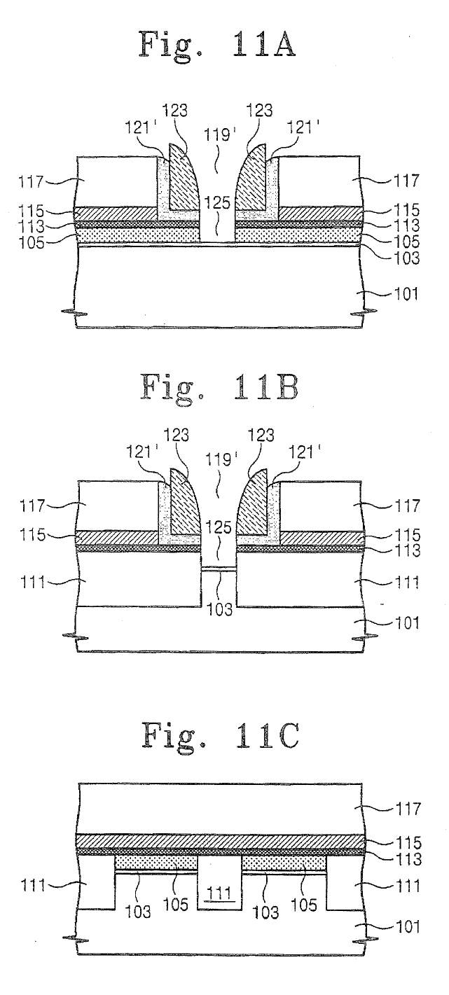

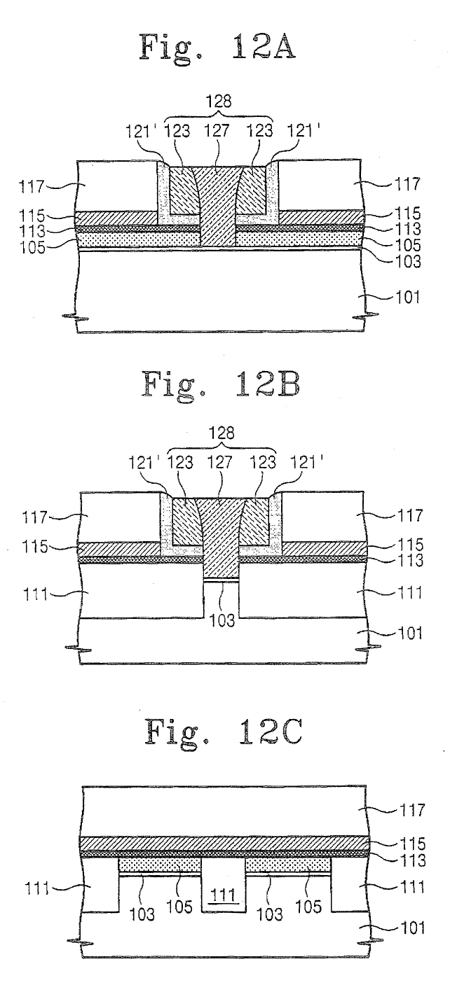

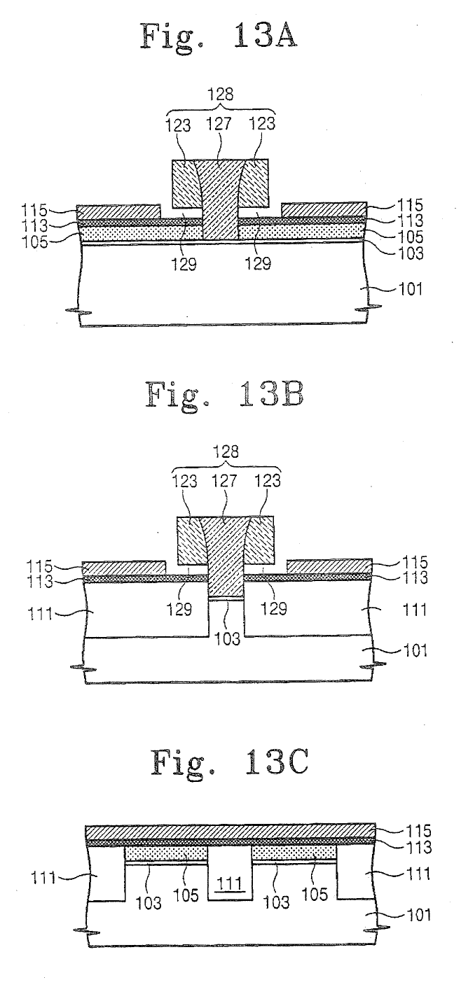

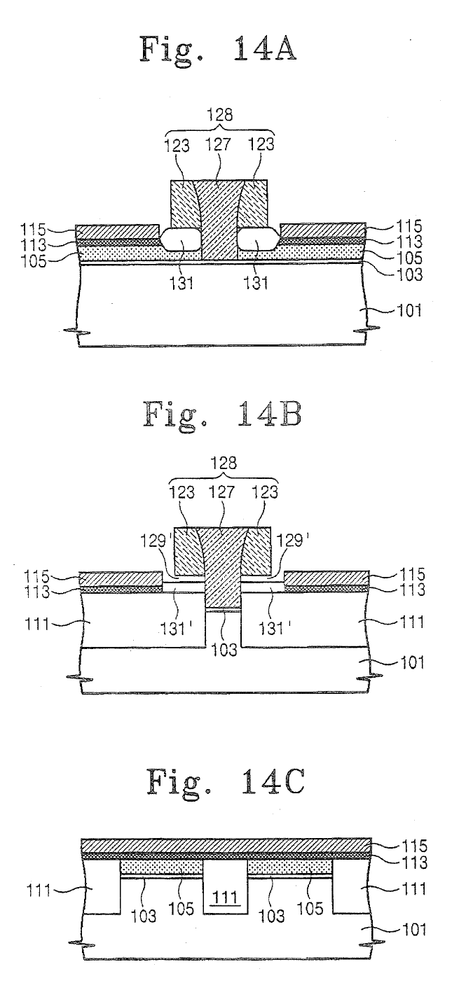

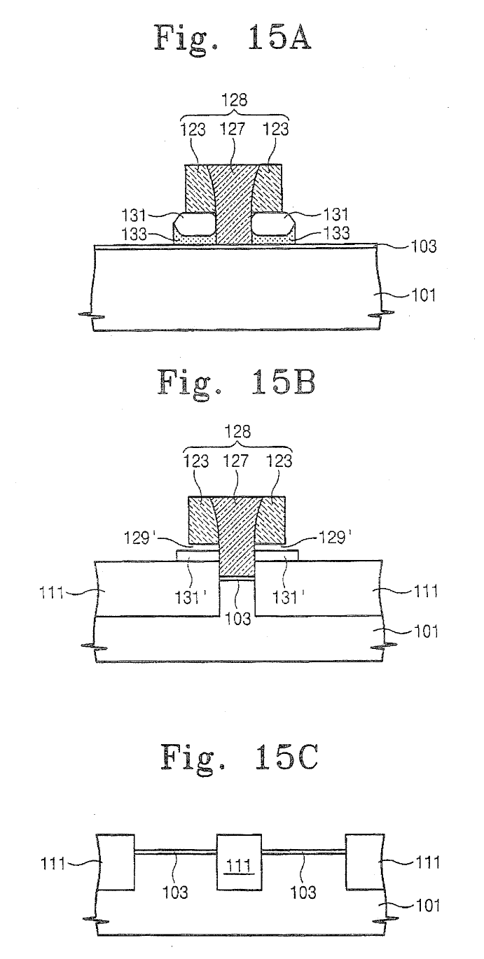

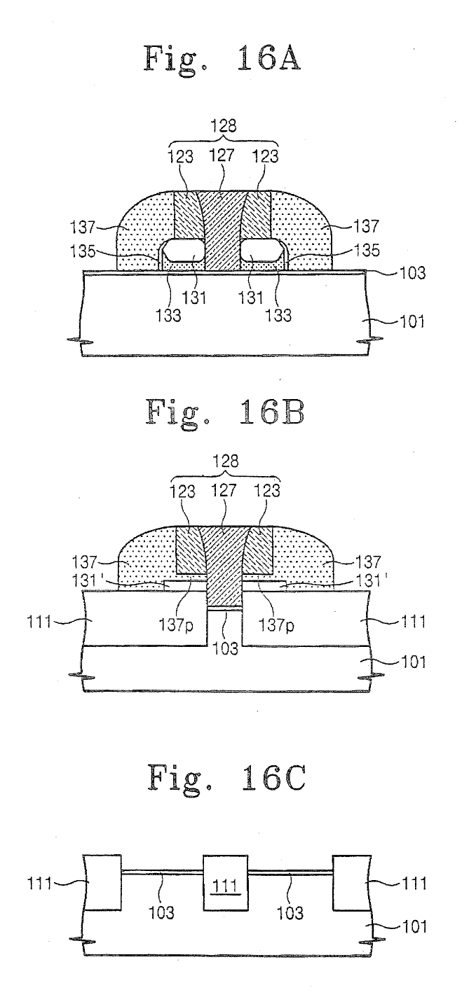

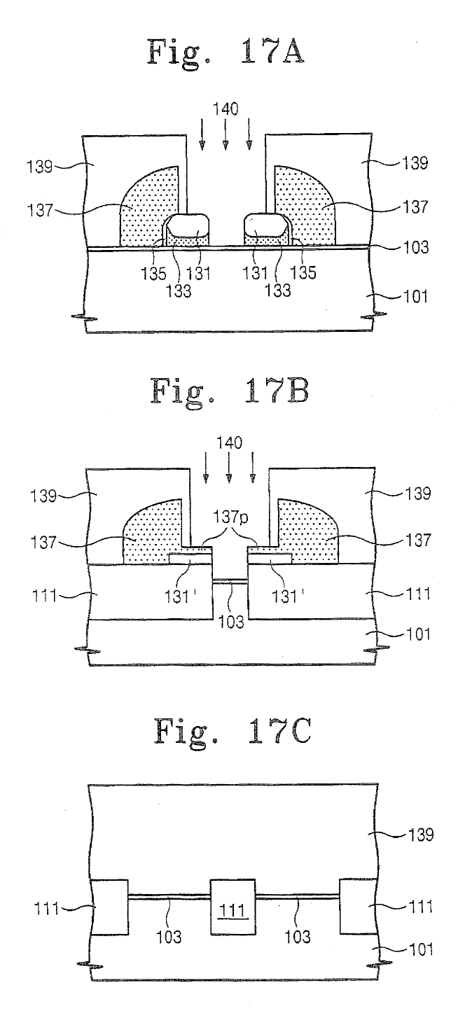

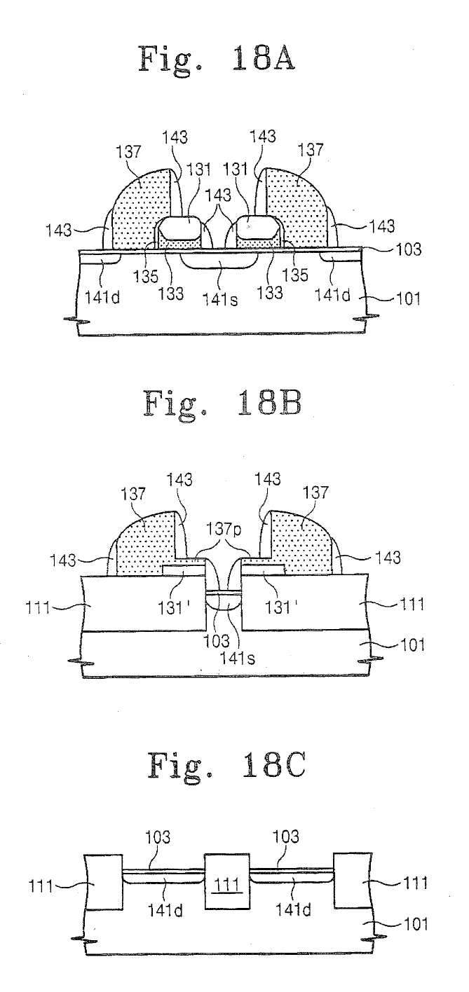

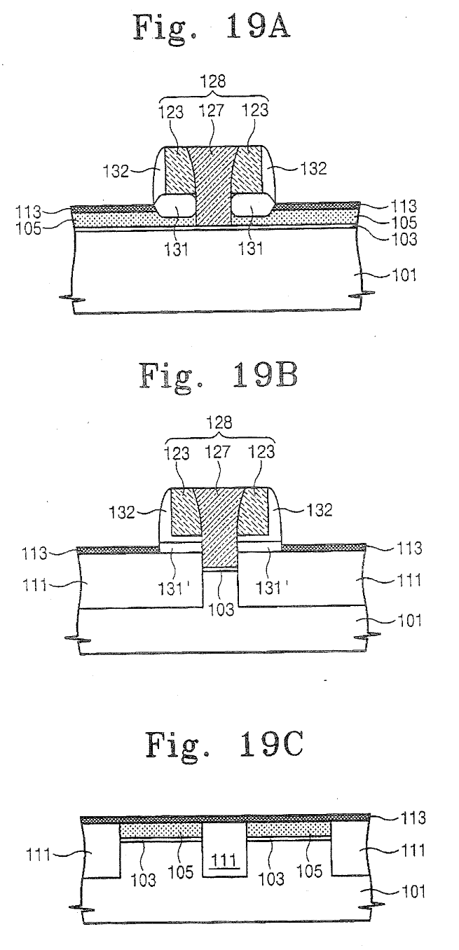

FIGS. 6A-C through FIGS. 19A-C are cross-sectional views that illustrate the formation of split-gate non-volatile memory cells according to some embodiments of the invention. In particular, the cross-sections shown in FIGS. 6A-19A are cross-sections taken along line I-I′ as shown in FIG. 3. The cross-sections shown in FIGS. 6B-19B correspond to views taken along line II-II′. FIGS. 6C-19C correspond to cross-sections taken along line III-III′.

According to FIGS. 6A-C, an insulator layer 103 is formed on a substrate 101. In some embodiments according to the invention, the insulator layer 103 is a thermally grown oxide, such as silicon oxide, formed to a thickness of about 50 Angstroms to about 150 Angstroms. A conductive layer 105 (used to provide the floating gate on the split-gate memory cell) is formed on the insulator layer 103. In some embodiments according to the invention, the first conductive layer 105 is a silicon layer formed to a thickness of about 300 Angstroms to about 1000 Angstroms. A photomask pattern 107 is formed on the first conductive layer 105 so that some portions of the first conductive layer 105 are exposed while others are covered by the photomask pattern 107. In some embodiments according to the invention, photomask pattern 107 is a silicon nitride material.

Referring to FIGS. 7A-C, the photomask pattern 107 is used to etch the substrate 101 to form a recess 109 therein. Referring to FIGS. 8A-C, a field oxide material is formed in the trench 109 and on the upper surfaces of the photomask pattern 107. A portion of the field oxide material and the photomask pattern 107 are removed using, for example, chemical mechanical polishing so that the first conductive layer 105 is exposed. Removal of the field oxide material and the photomask pattern 107 also provides for the formation of field oxide regions 111.

According to FIGS. 9A-C, a second conductive layer 113 is formed on the first conductive layer 105 above the portion of the substrate 101 where the floating gate is to be subsequently formed and on the field oxide region 111 adjacent to the floating gate. In some embodiments according to the invention, the second conductive layer 113 is a polysilicon material formed to a thickness less than about 500 Angstroms. An oxidation barrier layer 115 is formed on the second conductive layer 113. In some embodiments according to the invention, the oxidation barrier layer 115 is a silicon nitride layer formed to a thickness of about 500 Angstroms to about 1000 Angstroms.

A first sacrificial layer 117 is formed on the oxidation barrier layer 115. The first sacrificial layer 117 has an etching selectivity relative to the oxidation barrier layer 115. In some embodiments according to the invention, the first sacrificial layer 117 is formed to a thickness of about 2000 Angstroms to about 4000 Angstroms. The first sacrificial layer 117 can be formed using chemical vapor deposition.

The first sacrificial layer 117 and the oxidation barrier layer 115 are etched to form a recess 119 that exposes the second conductive layer 113 on the active region of the substrate (i.e., where the floating gate is to be formed) as well as on the field oxide region 111 as shown in FIGS. 9A and B respectively.

Referring to FIGS. 10A-C, a second sacrificial layer 121 is formed in the recess 119 including at the bottom of the recess 119 on the second conductive layer 113 to form a secondary recess 119′. In some embodiments according to the invention, the second sacrificial layer 121 is an oxide formed using chemical vapor deposition to a thickness of about 200 Angstroms to about 500 Angstroms.

A spacer material is deposited on the second sacrificial layer 121 inside the recess 119′ and outside the recess 119′. In some embodiments according to the invention, the spacer material is deposited to a thickness of about 1000 Angstroms to about 2000 Angstroms and is a material that has an etching selectivity relative to the second sacrificial layer 121, such as silicon nitride. The spacer material formed in the recess 119′ and outside the recess 119′ is etched-back to form inner spacer 123 inside the recess 119′ and to expose the second sacrificial layer 121 at a central portion of the bottom of the recess 119′.

Referring to FIGS. 11A-C, the etch-back of the inner spacer material continues to expose the upper surface of the first sacrificial layer 117 and the second sacrificial layer 121 between the first sacrificial layer 117 and a sidewall of the inner spacer 123 so that upper sidewall of the inner spacer 123 is exposed above the first and second sacrificial layers 117 and 121. The recess 119′ is further etched to remove the exposed portion of the second sacrificial layer 121 at a bottom of the recess 119′ and the underlying portions of the first and second conductive layers 105 and 113. As shown in FIG. 11B, the further etching in the recess 119′ removes the underlying portion of the second conductive layer 113 above the field oxide region 111 and can provide access to the substrate 101 for formation of the common source region shared by the opposing split-gate non-volatile memory cells.

According to FIGS. 12A-C, a silicon nitride blanket layer is deposited in the recess 119′ and on the upper surfaces of the first and second sacrificial layers 117 and 121. The silicon nitride blanket layer is planarized to expose the first sacrificial layer 117 to form a T-shaped sacrificial structure 128 including the inner spacer 123 and a center pillar 127.

According to FIGS. 13A-C, an etching process is used to remove the second sacrificial layer 121′ from around the sacrificial structure 128 to form a first gap above the active region (where a subsequent floating gate is to be formed) and a second gap above the field oxide region 111. As shown in FIG. 13A, the first gap exposes a portion of the second conductive layer 113, the first gap being defined by the sacrificial structure 128 above and the second conductive layer 113 below. As shown in FIG. 13B, the second gap exposes the second conductive layer 113 on the field oxide region 111, wherein the second gap is defined by the sacrificial structure 128 above and the second conductive layer 113 below.

According to FIGS. 14A-C, an oxidation process is performed to provide an oxide layer on the active regions between the opposing split-gate non-volatile memory cells and extending onto the adjacent field oxide regions 111 to form a raised oxide layer 131′. As shown in FIG. 14A, the full thickness of the second conductive layer 113 is oxidized in addition to a partial thickness of the first conductive layer 105 being oxidized to fill the first gap beneath the sacrificial structure 128. As shown in FIG. 14B, the oxidation process fully oxidizes the second conductive layer 113 in the second gap to provide the raised oxide layer 131′ and to leave a remaining gap portion 129′ above the raised oxide layer 131′ and below the sacrificial structure 128 on the field oxide region 111.

According to FIGS. 15A-C, the oxidation barrier layer 115 and the underlying second conductive layer 113 are removed from the substrate 101. Furthermore, a portion of the first conductive layer 105 is also removed from the substrate 101 while a portion of the first conductive layer 105 underlying the oxide layer 131 above the active regions remains. In some embodiments according to the invention, the oxide layer 131 is used as an etch mask to remove the oxidation barrier layer 115, the second conductive layer 113, and the portion of the first conductive layer 105 as described above. Accordingly, the etching process is used to form floating gates 133 that are self-aligned to the field oxide region 111 and to the oxide layers 131. As shown in FIG. 15B, the formation of the floating gate 133 is avoided on the field oxide region 111 due to the presence of the raised oxide layer 131′ and the absence of the first conductive layer 105 therefrom.

In some embodiments according to the invention, sacrificial spacers 132 can be formed on sidewalls of the sacrificial structure 128 prior to removal of the second conductive layer 113 and the portion of the first conductive layer 105 not covered by the oxide layer 131. As shown in FIG. 16B, the sacrificial spacer 132 extends between the sacrificial structure 128 and the raised oxide layer 131 to fill the remaining gap portion 129′ left unfilled during formation of the raised oxide layer 131′. In some embodiments according to the invention, the sacrificial spacer 132 is formed of a silicon nitride material. It will be understood that the sacrificial spacer 132 can be used to protect against over etching of the oxide layer 131. Furthermore, the amount of overlap of the sacrificial spacer 132 onto an upper surface of the sacrificial structure 128 can be adjusted to control how much the control gate overlaps the floating gate 133.

According to FIGS. 17A-C, a spacer 135 is formed on sidewalls of the floating gate 133 and the oxide layer 131. In some embodiments according to the invention, the spacers 135 are formed using a thermal oxidation process or thin film deposition process. A conductive layer is deposited on the structure including on the spacer 135 and sidewall of the sacrificial structure 128. The conductive material is etched back to form the control gate 137 that extends vertically adjacent to the sidewall of the floating gate 133 and the sidewall of the oxide layer 131 above the active regions in the substrate 101. Furthermore, the control gate 137 extends to cover a portion of the oxide layer 131 as shown in FIG. 17A.

As shown in FIG. 17B, the control gate 137 includes an extended portion 137p that extends between a bottom of the sacrificial structure 128 and an upper surface of the raised oxide layer 131′ to fill the remaining gap portion 129′ left unfilled during oxidation to form the raised oxide layer 131′.

According to FIGS. 18A-C, the sacrificial structure 128 is removed and a mask pattern 139 is formed on the structure. An ion implantation 140 is performed through openings in the mask pattern 139 to form a common source region 141s in the substrate 101.

According to FIGS. 19A-C, the common source region 141s is out-diffused using, for example, an annealing process. A spacer 143 is formed on a sidewall of the control gate 137 above the floating gates 133 and on the sidewalls of the raised oxide layer 131′ and the floating gate 133. In some embodiments according to the invention, the spacer 143 is formed by depositing a blanket layer of silicon nitride of a thickness of about 500 Angstroms to about 1000 Angstroms which is etched back so that the spacers 143 remain on the structure. A subsequent implant is performed (not shown) to form respective drain regions 141d in the substrate 101 associated with the opposing split-gate non-volatile memory cells. Also, additional backend processing steps can be provided to complete the split-gate non-volatile memory cells, such as formation of interlayer dielectric layers and metal wiring layers which can contact for example, the common source region 141s.

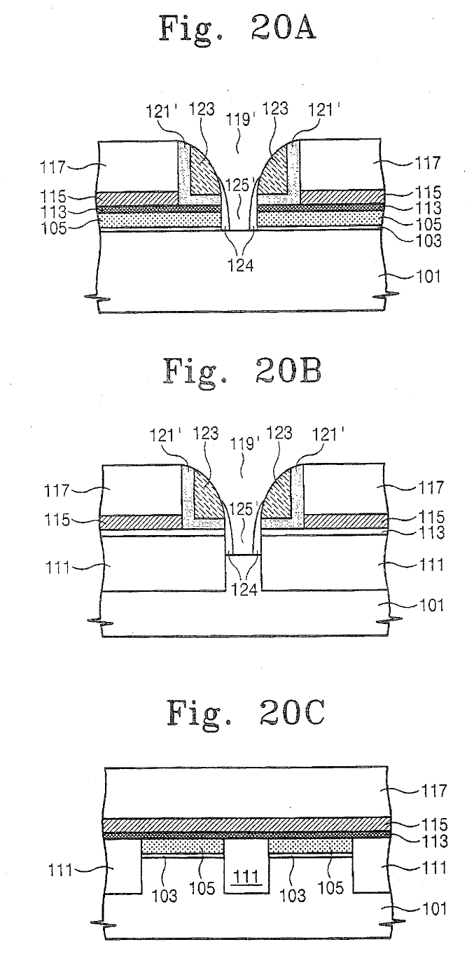

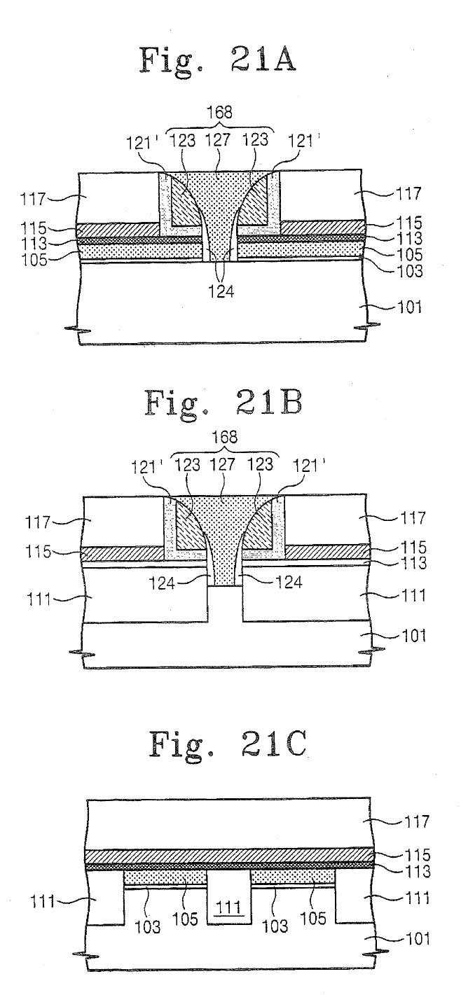

FIGS. 20A-C through FIGS. 21A-C are cross-sectional views, taken along lines I-I′, II-II′, and III-III′ respectively in FIG. 3, that illustrate the formation of split-gate memory cells according to some embodiments of the invention. Referring to FIGS. 20A-C, the structures described above in reference to FIGS. 6A-C through FIGS. 10A-C can be formed as a basis for further embodiments described herein with reference to FIGS. 20A-C through FIGS. 21A-C. In particular, as shown in FIGS. 20A-C, the recess 119′ is subject to further etching to remove the underlying portions of the second sacrificial layer 121′ and underlying portions of the first and second conductive layers 105 and 113 to expose a portion of the substrate 101 to form further recess 125′. A spacer is formed on a sidewall of the further recess 125′ that is defined by the first and second conductive layers 105 and 113. The spacer 124 can electrically isolate the first and second conductive layers 105 and 113 from a contact to be subsequently formed in the recess 119′ and further recess 125′.

According to FIGS. 21A-C, a conductive material 127 is formed in the recess 119′ and the further recess 125′ including on the spacer 124. The conductive material is deposited outside the recess 119′ and on an upper surface of the first sacrificial layer 117. A planarization process is used (such as chemical mechanical planarization) to remove portions of the conductive material 127 outside the recess 119′ to provide a contact structure 168 to electrically coupled to a subsequently formed common source region in the substrate below. Furthermore, subsequent processing steps can be used as outlined above in reference to FIGS. 13A-C through FIGS. 19A-C to complete the split-gate memory cells according to some embodiments of the invention.

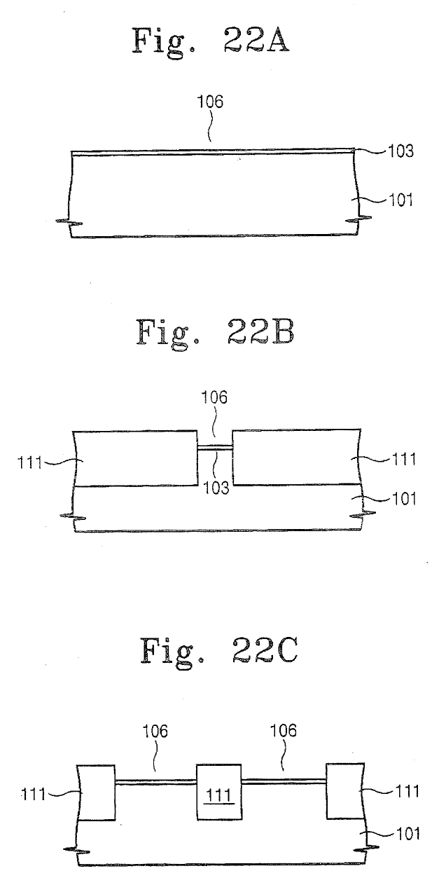

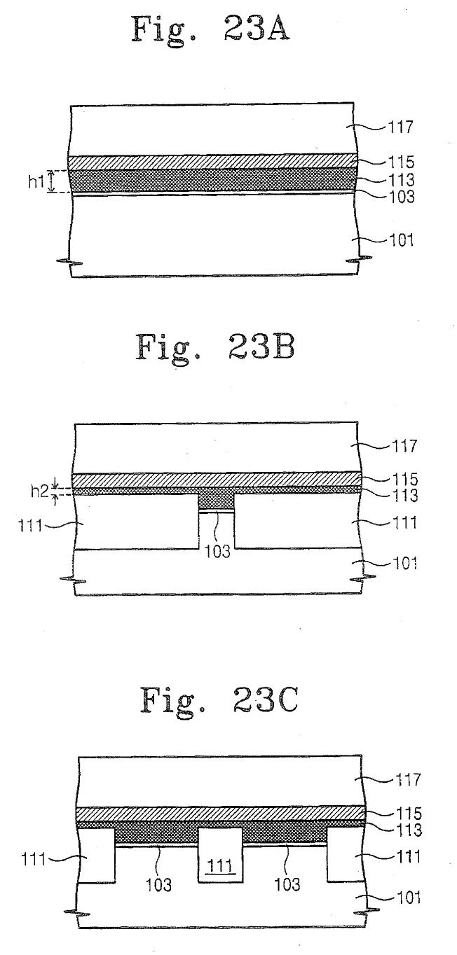

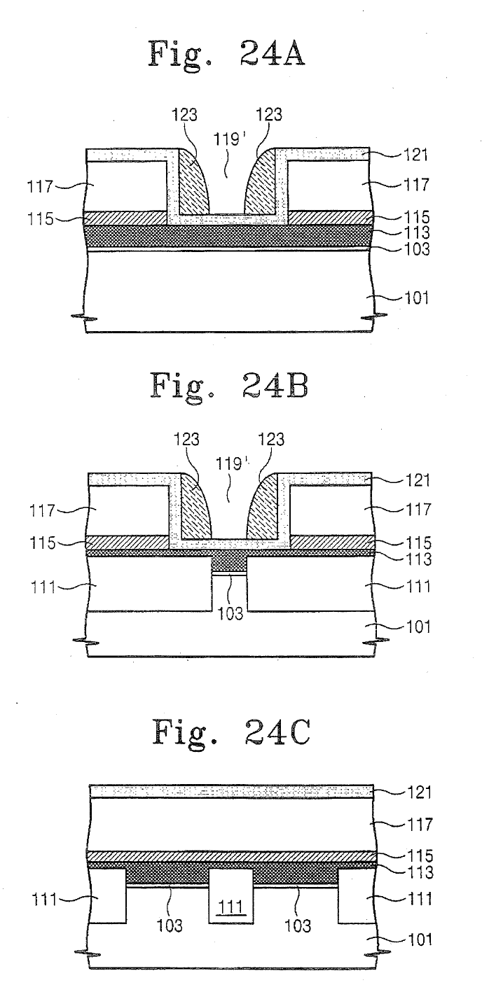

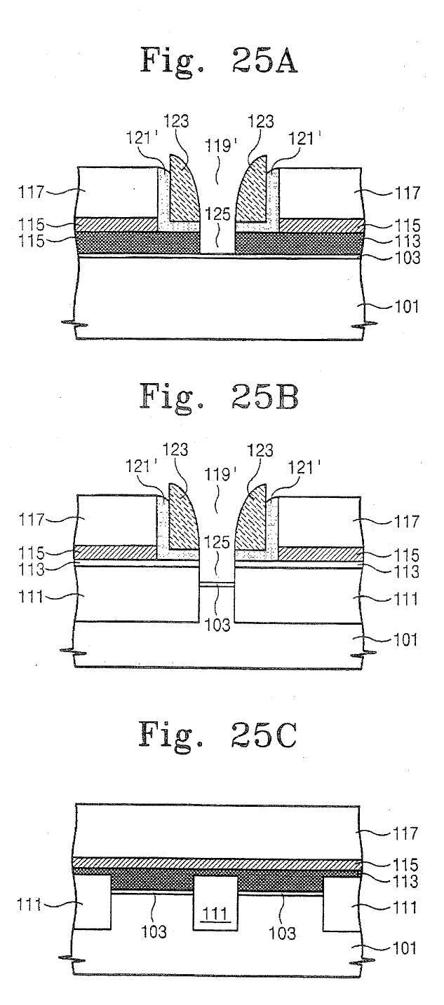

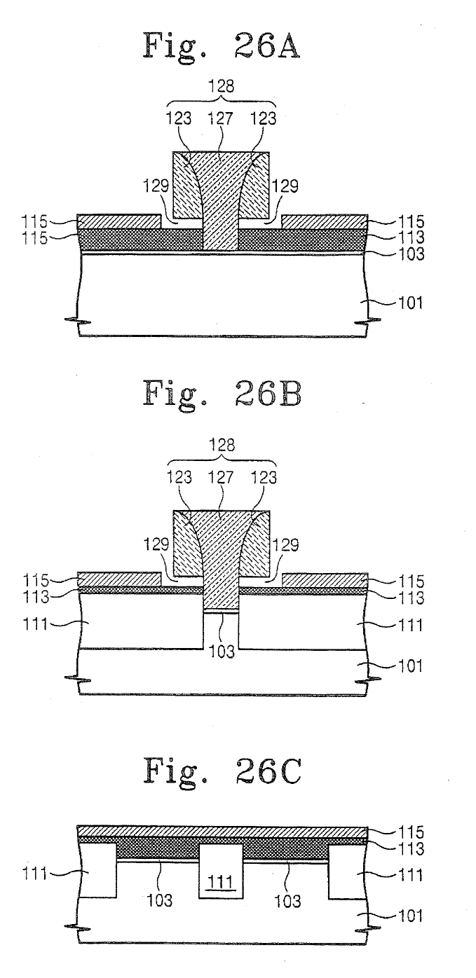

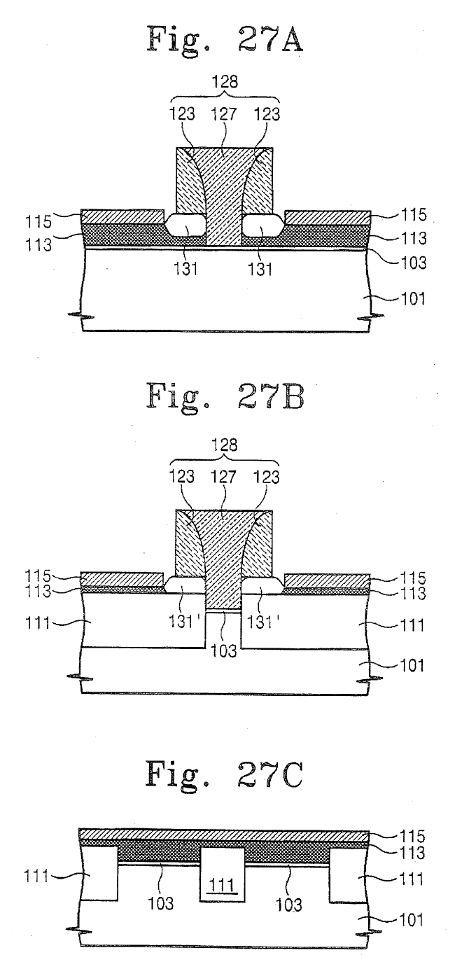

FIGS. 22A-C through FIGS. 27A-C are cross-sectional views, taken along lines I-I′, II-II′, and III-III′ respectively in FIG. 3, that illustrate the formation of split-gate non-volatile memory cells according to some embodiments of the invention. In particular, FIGS. 22A-C through FIGS. 27A-C illustrate method embodiments according to the invention where a single conductive layer is formed rather than the two conductive layers as described above in reference to FIGS. 4-21.

Referring to FIGS. 22A-C, an insulator layer 103 is formed on the substrate 101 and a silicon nitride layer (not shown) is formed on the insulator layer 103. A mask pattern is formed on the silicon nitride layer including openings therein so that the underlying layers including the silicon nitride, the insulator layer 103 and the substrate 101 can be patterned.

Portions of the silicon nitride layer, the insulator layer 103 and the substrate 101 are etched using the mask pattern. The mask pattern is removed and a field oxide material is deposited on the substrate and is planarized to provide field oxide regions 111 adjacent to active regions on which opposing split-gate memory cells are to be formed. As shown in FIGS. 22A and B, field oxide region 111 is raised relative to the insulator layer 103 on the area of the substrate 101 where the active regions are to be formed (i.e., as shown in FIG. 22A).

According to FIGS. 23A-C, a conductive layer 113 is deposited on the insulator layer 103 and the field oxide regions 111 and is planarized. As shown in FIGS. 23A and B, the thickness of the conductive layer 113 on the active regions is greater than the thickness of the conductive layer 113 on the field oxide region 111. In some embodiments according to the invention, the conductive layer 113 is a silicon layer.

According to FIGS. 24A-C, an oxidation barrier layer 115 is formed on the conductive layer 113 followed by formation of the first sacrificial 117. The first sacrificial layer 117 and the oxidation barrier layer 115 are etched to form the recess 119′. The second sacrificial layer 121 is formed in the recess 119′ and outside the recess 119′ on an upper surface of the first sacrificial layer 117. Furthermore, an inner spacer material is formed on an upper surface of the second sacrificial layer 121 outside the recess 119′ and inside the recess 119′. The inner spacer material is etched back so that an inner spacer 123 is formed on the sidewall of the recess 119′. As shown in FIGS. 24A and B, the inner spacer 123 leaves a central portion of the recess 119′ uncovered so that a portion of the second sacrificial layer 121 is exposed after formation of the inner spacer 123.

According to FIGS. 25A-C, the etch back continues so that the first sacrificial layer 117 and second sacrificial layer 121′ thereunder are exposed. Furthermore, a further recess 125 is formed below the recess 119′ when removing portions of the second sacrificial layer 121′ and conductive layer 113 underlying exposed portion of the sacrificial layer 121 in the recess 119′.

According to FIGS. 26A-C, a center pillar 127 is formed in the recess 119′ and further recess 125 to form a T-shaped sacrificial structure 128. Furthermore, the second sacrificial layer 121′ is removed from around the sacrificial structure 128 to provide first and second gaps between the lower surface of the sacrificial structure 128 and an upper surface of the first conductive layer 113 on both the active region and the field oxide region 111.

According to FIGS. 27A-C, a partial thickness of the conductive layer 113 on the portion of the substrate in which the active regions are to be formed is oxidized to provide the formation of the oxide layer 131. As shown in FIG. 27A, a full thickness of the conductive layer 113 is oxidized to form the raised oxide layer 131′ on the field oxide regions 111. As shown in FIGS. 27 A and B, the oxidation of the conductive layer 113 fills both the first and second gaps.

Further backend processing steps can be provided as discussed above in reference to FIGS. 15A-C through FIGS. 19A-C. Furthermore, the embodiments described above in reference to FIGS. 22A-C through FIGS. 27A-C can be combined with aspects described above in reference to FIGS. 20A-C through FIGS. 21A-C.

As described above, in some embodiments according to the invention, an oxide layer can be formed to cover first and second adjacent floating gates and a field oxide region, wherein the oxide layer electrically isolates the first and second adjacent floating gates from one another. For example, the oxide layer can extend from on the active region above the floating gate onto the adjacent field oxide region. Furthermore, the portion of the oxide layer that extends onto the field oxide region can be raised relative to the oxide layer that is above the floating gate.

Accordingly, a surface of the raised oxide layer is at a higher level than a surface of the oxide layer located above the floating gate. Extending the oxide layer from on the floating gate to on the field oxide region (and further onto the floating gate in the adjacent memory cell) can electrically isolate the floating gates in the adjacent memory cells from one another. Furthermore, the floating gates can be formed self-aligned to the field oxide regions (and isolated from one another via the oxide layer including the raised oxide layer on the field oxide between adjacent split-gate memory cells). The oxide layer including the raised oxide layer on the field oxide region may improve the self-alignment of the floating gates in forming the split-gate memory cells according to some embodiments of the invention.

Many alterations and modifications may be made by those having ordinary skill in the art, given the benefit of the present disclosure, without departing from the spirit and scope of the invention. Therefore, it must be understood that the illustrated embodiments have been set forth only for the purposes of example, and that it should not be taken as limiting the invention as defined by the following claims. The following claims are, therefore, to be read to include not only the combination of elements which are literally set forth but all equivalent elements for performing substantially the same function in substantially the same way to obtain substantially the same result. The claims are thus to be understood to include what is specifically illustrated and described above, what is conceptually equivalent, and also what incorporates the essential idea of the invention.

What is claimed:

1. A split-gate non-volatile memory device comprising:
a raised oxide layer on a field oxide region between adjacent split-gate memory cells, the raised oxide layer extending onto first and second floating gates included in the adjacent split-gate memory cells covered by a wordline electrically coupled to respective control gates included in the adjacent split-gate memory cells.

2. A memory device according to claim 1 wherein central upper portions of the first and second floating gates are lower than a surface of the field oxide region.

3. A memory device according to claim 1 wherein the raised oxide layer comprises a thermally oxidized polysilicon layer.

4. A memory device according to claim 1 wherein the floating gates are self aligned to the field oxide regions.

5. A memory device according to claim 1 wherein the raised oxide layer extends onto the active region to cover the floating gates.

6. A memory device according to claim 5 wherein the raised oxide layer on the field oxide region is thinner than a portion of the raised oxide layer that extends onto the active region to cover the first and second floating gates.

7. A memory device according to claim 5 further comprising:
a first spacer on a side wall of the control gates above the floating gates; and
a second spacer on side walls of the raised oxide layer and the floating gates.

8. A split-gate non-volatile memory device comprising:
first and second adjacent floating gates self-aligned to a field oxide region therebetween;
an oxide layer covering the first and second adjacent floating gates and the field oxide region, the oxide layer electrically isolating the first and second adjacent floating gates from one another; and
a control gate on the oxide layer on the first and second adjacent floating gates.

9. A memory device according to claim 8 wherein central upper portions of the first and second floating gates are lower than a surface of the field oxide region.

10. A memory device according to claim 8 wherein the oxide layer comprises a thermally oxidized polysilicon layer.

11. A memory device according to claim 8 wherein the oxide layer extends onto the active region to cover the floating gates.

12. A memory device according to claim 11 wherein the oxide layer on the field oxide region is thinner than a portion of the oxide layer that extends onto the active region to cover the first and second floating gates.

13. A memory device according to claim 11 further comprising:
a first spacer on a side wall of the control gates above the floating gates; and
a second spacer on side walls of the oxide layer and the floating gates.
